(19) United States
(12) Patent Application Publication
(10) Pub. No.: US 2011/0242869 A1
(43) Pub. Date: Oct. 6, 2011

(54) THREE-DIMENSIONAL STACKED SEMICONDUCTOR INTEGRATED CIRCUIT AND CONTROL METHOD THEREOF

(75) Inventors: Hyung Dong Lee, Ichon-shi (KR); Duk Su Chun, Ichon-shi (KR); Hyun Seok Kim, Ichon-shi (KR)

(73) Assignee: Hynix Semiconductor Inc., Ichon-shi (KR)

(21) Appl. No.: 12/840,250

(22) Filed: Jul. 20, 2010

(30) Foreign Application Priority Data
Mar. 31, 2010 (KR) 10-2010-0029100

(51) Int. Cl. G11C 5/02; G11C 8/00

(52) U.S. Cl. 365/51; 365/230.03; 365/191

(57) ABSTRACT

A three-dimensional stacked semiconductor integrated circuit including a plurality of stacked chips. The semiconductor integrated circuit is configured to simultaneously select the plurality of chips in response to an external command and an address, and to activate one of memory banks which are aligned on the same line in a vertical direction, among a plurality of memory banks included in the plurality of chips.

### CROSS-REFERENCES TO RELATED APPLICATION

The present application claims priority under 35 U.S.C. §119(a) to Korean Application No. 10-2010-0029100, filed on Mar. 31, 2010, in the Korean Intellectual Property Office, which is incorporated herein by reference in its entirety as if set forth in full.

### BACKGROUND

1. Technical Field

The present invention relates to a semiconductor integrated circuit, and more particularly, to a three-dimensional stacked semiconductor apparatus and a control method thereof.

2. Related Art

Semiconductor integrated circuits are formed by including two or more chips in a single device to improve integration efficiency. As a representative example, a three-dimensional stacked semiconductor integrated circuit using TSVs (through-silicon vias) has been developed.

FIG. 1 is a cross-sectional view illustrating a conventional three-dimensional stacked semiconductor integrated circuit, and FIG. 2 is a layout diagram of a chip of the conventional three-dimensional stacked semiconductor integrated circuit. Referring to FIG. 1, a conventional three-dimensional stacked semiconductor integrated circuit 1 has a structure in which a plurality of chips CHIP0 through CHIP3 are stacked on a substrate 11 and are coupled with one another by way of TSVs.

Referring to FIG. 2, taking as an example each of the chips in the three-dimensional stacked semiconductor integrated circuit 1, chip CHIP1 has a plurality of memory banks BK0 through BK7. TSVs for interfacing data, signals, etc. are disposed at the center portion of chip CHIP1, and TSVs for supplying a power supply voltage or a ground voltage are disposed at the peripheral portions of chip CHIP1.

Further, in each of the remaining chips CHIP0, CHIP2 and CHIP3, a plurality of memory banks BK0 through BK7 and TSVs are disposed in a similar manner as in chip CHIP1.

The memory banks BK0 of all the chips CHIP0 through CHIP3 are aligned on the same line in the vertical direction, and the remaining memory banks BK1 through BK7 of all the chips CHIP0 through CHIP3 are aligned in a similar manner as the memory banks BK0 does.

A three-dimensional stacked semiconductor integrated circuit has a plurality of memory banks. For example, the three-dimensional stacked semiconductor integrated circuit 1 shown in FIGS. 1 and 2 has 32 memory banks.

In designing a three-dimensional stacked semiconductor integrated circuit, the development of a technique for efficiently controlling the operations of a plurality of memory banks in consideration of certain problems, such as those associated with current consumption and heat generation, caused by changes in operating circumstances is necessary.

### SUMMARY

A three-dimensional stacked semiconductor integrated circuit capable of efficiently controlling operations of a plurality of memory banks in consideration of changes in operating circumstances is described herein.

In one embodiment of the present invention, a three-dimensional stacked semiconductor integrated circuit includes a plurality of stacked chips, wherein the semiconductor integrated circuit is configured to simultaneously select the plurality of chips in response to an external command and an address and to activate one of memory banks, which are aligned on the same line in a vertical direction, among a plurality of memory banks included in the plurality of chips.

In another embodiment of the present invention, a three-dimensional stacked semiconductor integrated circuit having a plurality of stacked chips includes: a select signal generation circuit disposed in any one of the plurality of chips and configured to generate a selection signal for selectively activating a plurality of memory banks provided in the plurality of chips, wherein the select signal generation circuit is configured to simultaneously select the plurality of chips in response to an external command and an address, and to activate one of memory banks which are aligned on the same line in a vertical direction, among the plurality of memory banks.

In another embodiment of the present invention, a method for controlling a three-dimensional stacked semiconductor integrated circuit including a plurality of stacked chips includes the steps of: selecting one from the groups of memory banks aligned on the same line in a vertical direction among a plurality of memory banks included in the plurality of chips, using a bank address; and activating one of the memory banks of the selected group, using a slice address.

### BRIEF DESCRIPTION OF THE DRAWINGS

Features, aspects, and embodiments are described in conjunction with the attached drawings, in which:

FIG. 1 is a cross-sectional view illustrating a conventional three-dimensional stacked semiconductor integrated circuit;

FIG. 2 is a layout diagram of a chip of the conventional three-dimensional stacked semiconductor integrated circuit;

FIG. 3 is a block diagram illustrating a three-dimensional stacked semiconductor integrated circuit in accordance with an embodiment of the present invention;

FIG. 4 is a block diagram illustrating the configuration of the select signal generation circuit shown in FIG. 3;

FIG. 5 is an operation timing diagram of the three-dimensional stacked semiconductor integrated circuit in accordance with the embodiment of the present invention;

FIG. 6 is a block diagram illustrating a three-dimensional stacked semiconductor integrated circuit in accordance with another embodiment of the present invention;

FIG. 7 is a block diagram illustrating the configuration of the select signal generation circuit shown in FIG. 6;

FIG. 8 is a circuit diagram illustrating the configuration of a column selection section of the column selection unit shown in FIG. 7;

FIG. 9 is a circuit diagram illustrating the configuration of the first latch shown in FIG. 8;

FIG. 10 is an operation tinning diagram of the select signal generation circuit shown in FIG. 7; and

FIG. 11 is an operation tinning diagram of the three-dimensional stacked semiconductor integrated circuit in accordance with another embodiment of the present invention.

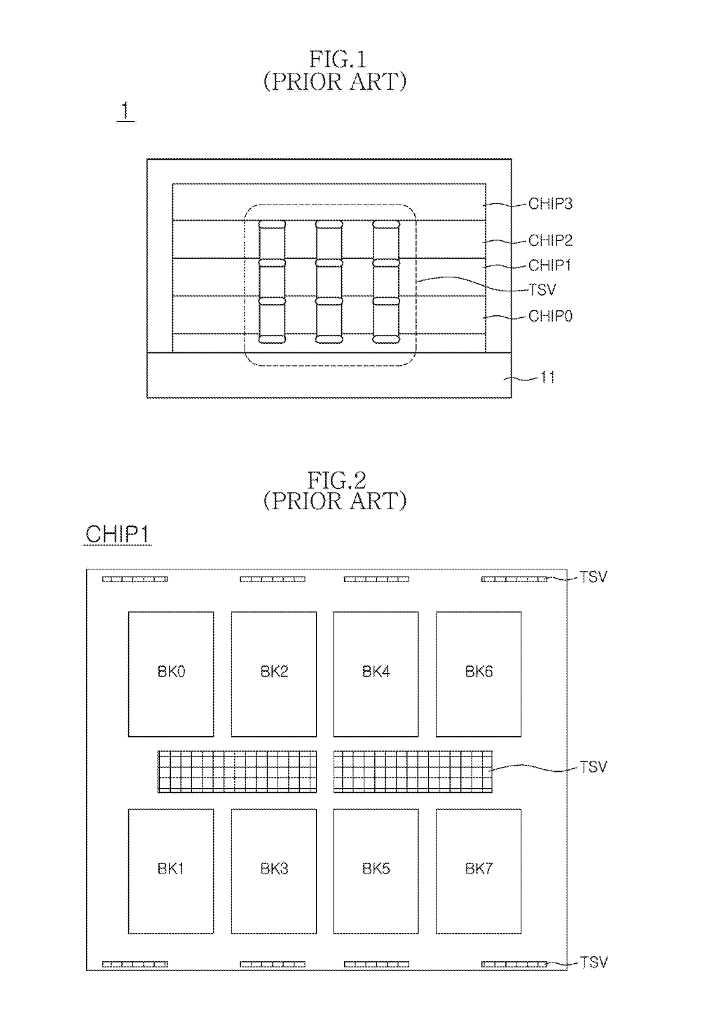

### DETAILED DESCRIPTION

A three-dimensional stacked semiconductor integrated circuit and a control method thereof according to the present invention is described below with reference to the accompanying drawings through exemplary embodiments.

In one embodiment of the present invention, each of a plurality of three-dimensionally stacked chips is controlled separately.

That is to say, in the embodiment of the present invention, a plurality of chips CHIP0 through CHIP3 are distinguished from one another using external commands, and a plurality of memory banks BK0 through BK7 are distinguished from one another using bank addresses.

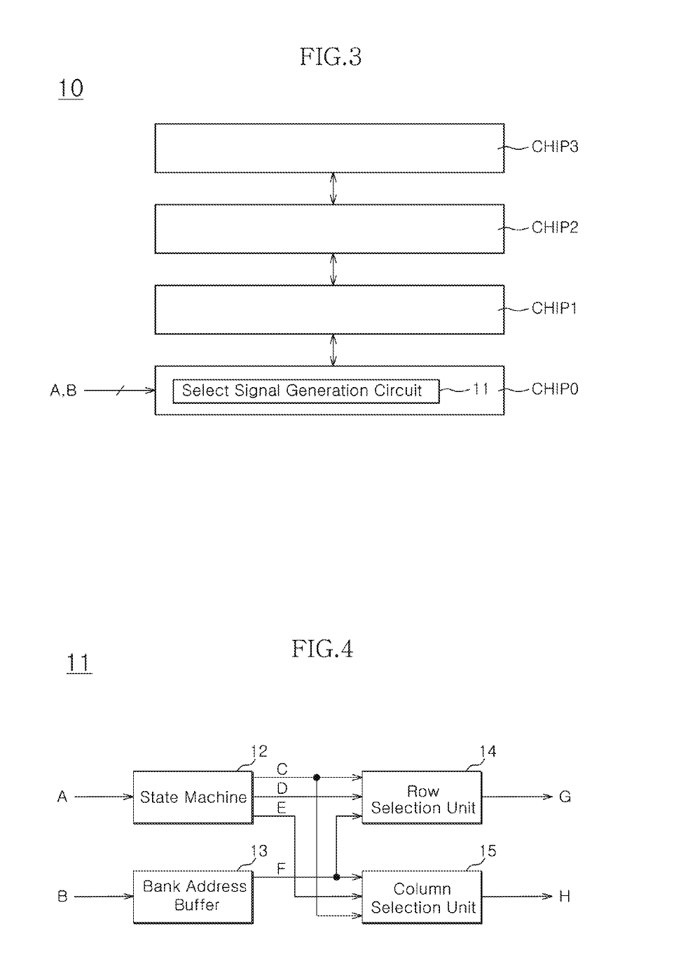

FIG. 3 is a block diagram illustrating a three-dimensional stacked semiconductor integrated circuit 10 in accordance with an embodiment of the present invention. Referring to FIG. 3, the three-dimensional stacked semiconductor integrated circuit 10 in accordance with an embodiment of the present invention includes a plurality of chips CHIP0 through CHIP3.

One of the plurality of chips CHIP0 through CHIP3 (for example, chip CHIP0) has a select signal generation circuit 11.

Among the plurality of chips CHIP0 through CHIP3, chip CHIP0 may be a master chip, and the remaining chips CHIP1 through CHIP3 may be slave chips.

The plurality of chips CHIP0 through CHIP3 are interconnected with each other through TSVs. Therefore, control efficiency can be improved by designating one of the plurality of chips CHIP0 through CHIP3 as a master chip and the remaining chips as slave chips.

Each of the plurality of chips CHIP0 through CHIP3 can be configured in the manner shown in FIG. 2.

It is possible to configure slave chips in a manner shown in FIG. 2 and the master chip to include the select signal generation circuit 11 without any memory bank.

The select signal generation circuit 11 is configured to select and activate a specific memory bank of a specific chip based on input signals A and B.

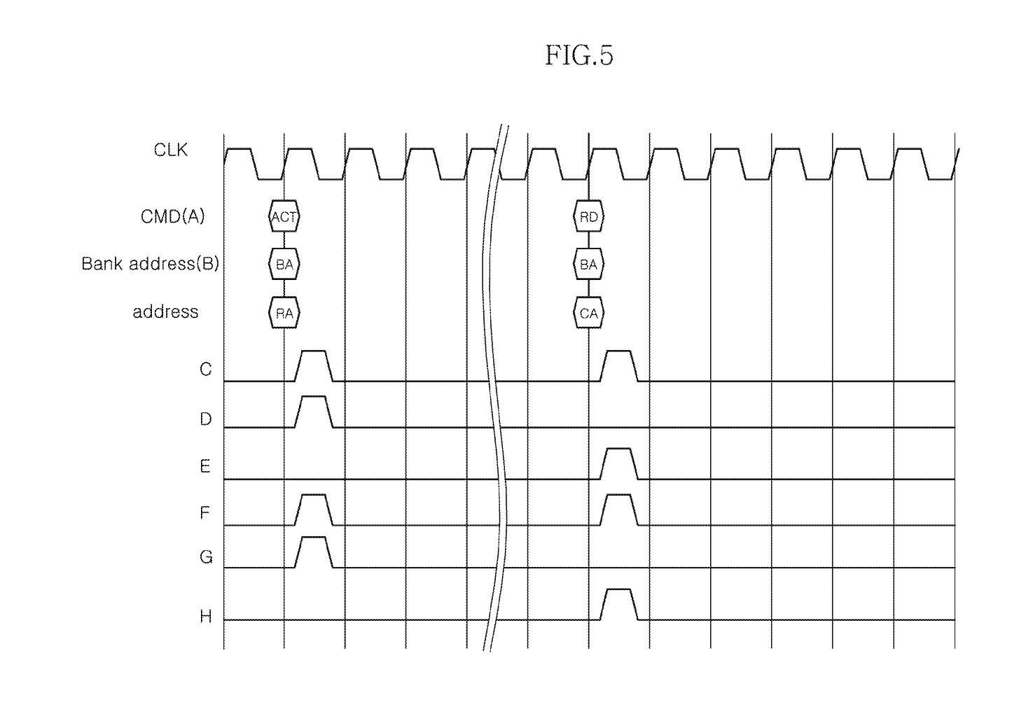

FIG. 4 is a block diagram illustrating the configuration of the select signal generation circuit shown in FIG. 3. Referring to FIG. 4, the select signal generation circuit 11 includes a state machine 12, a bank address buffer 13, a row selection unit 14, and a column selection unit 15.

The state machine 12 is configured to decode the input signal A and to generate a chip select address C, a row active signal D and a column active signal E.

The input signal A includes chip selection signals /CS<0:3> and various command signals. The chip select address C is an address for selecting a specified chip according to the chip selection signals /CS<0:3>.

The row active signal D is a signal which is acquired by decoding a row active command for a chip/bank.

The column active signal E is a signal which is acquired by decoding a read/write command for a chip/bank.

The bank address buffer 13 is configured to decode the input signal B, that is, a bank address BA, and to generate a decoded bank address F.

The row selection unit 14 is configured to generate a row selection signal G for selecting a row of a specified memory bank among the entire memory banks in a row active cycle, according to the chip select address C, the row active signal D and the decoded bank address F.

In this embodiment of the present invention, since there are 4 chips each having 8 memory banks, the row selection signal G may have 32 bits.

The column selection unit 15 is configured to generate a column selection signal H for selecting a column of a specific memory bank among all of the memory banks in a column active cycle, according to the chip select address C, the column active signal E and the decoded bank address F.

In this embodiment of the present invention, since there are 4 chips each having 8 memory banks, the column selection signal H may also have 32 bits.

FIG. 5 is an operation timing diagram of the three-dimensional stacked semiconductor integrated circuit in accordance with the embodiment of the present invention. Operation of the three-dimensional stacked semiconductor integrated circuit 10 in accordance with the above-configured embodiment of the present invention will be described with reference to FIG. 5.

First, describing the row active cycle, as an active command ACT is inputted along with a bank address BA and a row address RA, the state machine 12 generates the chip select address C and the row active signal D.

The bank address buffer 13 generates the decoded bank address F according to the bank address BA.

The row selection unit 14 generates the row selection signal G according to the chip select address C, the row active signal D and the decoded bank address F.

A row active operation is performed as one of the plurality of memory banks BK0 through BK7 is selected according to the row selection signal G.

Then, describing the column active cycle, as a read command RD is inputted along with a bank address BA and a column address CA, the state machine 12 generates the chip select address C and the column active signal E.

The bank address buffer 13 generates the decoded bank address F according to the bank address BA.

The column selection unit 15 generates the column selection signal H according to the chip select address C, the column active signal E and the decoded bank address F.

One of the plurality of memory banks BK0 through BK7 is selected according to the column selection signal H, leading to a column-activation operation, followed by a read operation.

In a three-dimensional stacked semiconductor integrated circuit 100 in accordance with another embodiment of the present invention, a plurality of memory banks BK0 through BK7 are divided into channels in the vertical direction and slices in the horizontal direction.

Each channel may be defined in units of memory banks aligned on the same vertical line. Memory banks in the same channel share a TSV.

For example, the same numbered memory banks BK0 of the plurality of chips CHIP0 through CHIP3 may constitute a first channel, the same numbered memory banks BK1 of the plurality of chips CHIP0 through CHIP3 may constitute a second channel, . . . , and the same numbered memory banks BK7 of the plurality of chips CHIP0 through CHIP3 may constitute an eighth channel.

Each slice may be defined in units of memory banks placed on the same horizontal line.

For example, the memory banks BK0 through BK7 of the chip CHIP0 may constitute a first slice, the memory banks BK0 through BK7 of the chip CHIP1 may constitute a second slice, the memory banks BK0 through BK7 of the chip CHIP2 may constitute a third slice, and the memory banks BK0 through BK7 of the chip CHIP3 may constitute a fourth slice.

In another embodiment of the present invention, one of the memory banks of a particular channel, which belongs to a particular slice, is selected and activated.

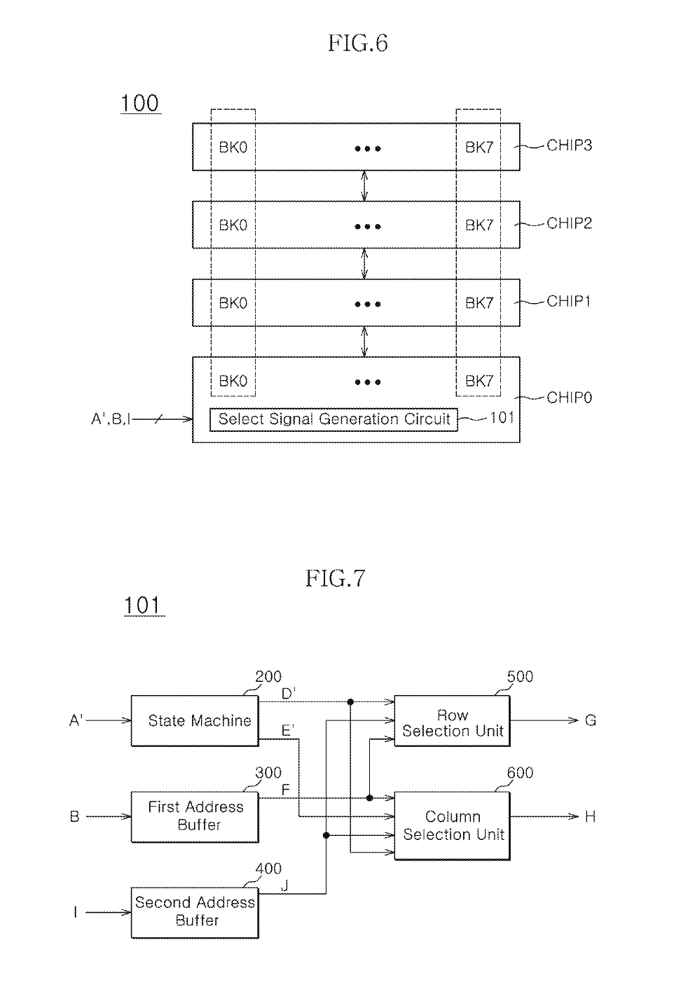

FIG. 6 is a block diagram illustrating a three-dimensional stacked semiconductor integrated circuit in accordance with another embodiment of the present invention. Referring to FIG. 6, the three-dimensional stacked semiconductor integrated circuit 100 in accordance with another embodiment of the present invention includes a plurality of chips CHIP0 through CHIP3.

One of the plurality of chips CHIP0 through CHIP3 (for example, chip CHIP0) has a select signal generation circuit 101.

Among the plurality of chips CHIP0 through CHIP3, chip CHIP0 may be a master chip, and the remaining chips CHIP1 through CHIP3 may be slave chips.

The plurality of chips CHIP0 through CHIP3 are interfaced through TSVs. Therefore, control efficiency can be improved by designating one of the plurality of chips CHIP0 through CHIP3 as a master chip and the remaining chips as slave chips.

The plurality of chips CHIP0 through CHIP3 may be configured in the manner shown in FIG. 2.

It is possible to configure slave chips in a manner shown in FIG. 2 and the master chip to include the select signal generation circuit 101 without any memory bank.

The select signal generation circuit 101 is configured to select and activate a specific memory bank of a specific channel based on input signals A′, B and I.

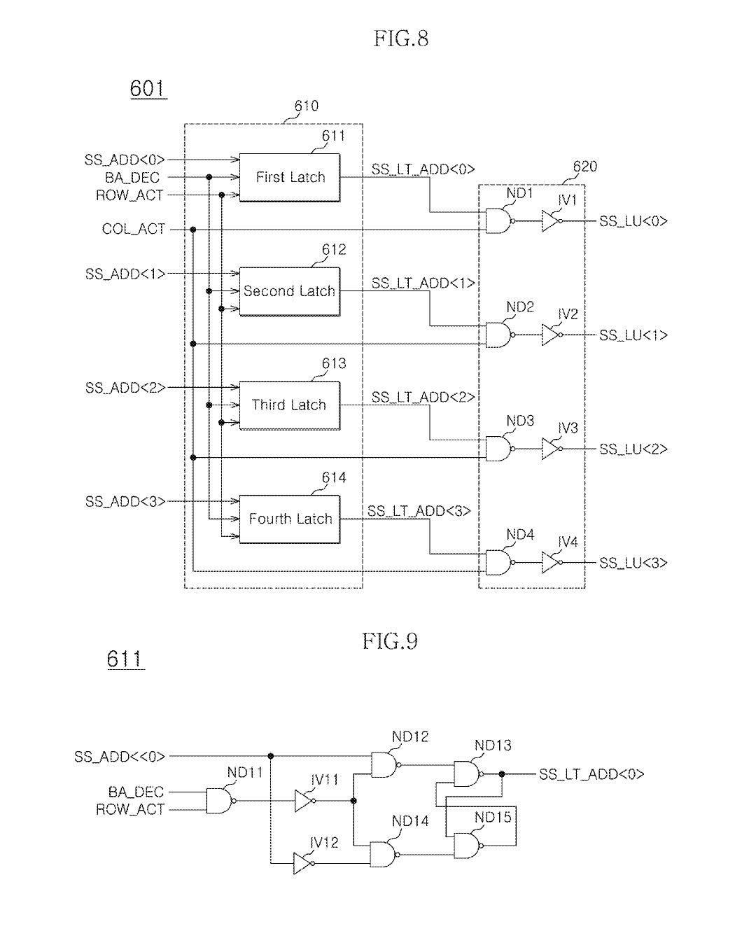

FIG. 7 is a block diagram illustrating the configuration of the select signal generation circuit shown in FIG. 6. Referring to FIG. 7, the select signal generation circuit 101 includes a state machine 200, a first address buffer 300, a second address buffer 400, a row selection unit 500, and a column selection unit 600.

The state machine 200 is configured to decode the input signal A′ and to generate a row active signal D′ and a column active signal E′.

The input signal A′ includes a chip selection signal /CS and various command signals. In another embodiment of the present invention, since all chips are recognized as one, a 1-bit chip selection signal /CS for only determining whether or not a selection is made may be used.

The row active signal D′ is a signal which is acquired by decoding a row active command for a chip/bank.

The column active signal E′ is a signal which is acquired by decoding a column active command for a chip/bank.

The first address buffer 300 is configured to decode the input signal B, that is, a bank address BA, and to generate a decoded bank address F.

The second address buffer 400 is configured to decode the input signal I and to generate a slice address J for selecting a slice.

The input signal I may use a row address, a bank address or a column address. In another embodiment of the present invention, the input signal I uses a portion of the upper bits of a row address. If a semiconductor integrated circuit has 4 slices, the input signal I may include a 2-bit row address.

The row selection unit 500 is configured to generate a row selection signal G for selecting a row of any one of the entire memory banks according to the row active signal D′, the decoded bank address F and the slice address J.

In another embodiment of the present invention that has 4 chips each having 8 memory banks, the row selection signal G may have 32 bits.

The column selection unit 600 is configured to generate a column selection signal H for selecting a column of one of the memory banks according to the row active signal D′, the column active signal E′, the decoded bank address F and the slice address J.

The column selection unit 600 is configured to store the slice address J, which is generated in a row active cycle, and to generate the column selection signal H with reference to the slice address J in a column active cycle.

In another embodiment of the present invention that has 4 chips each having 8 memory banks, the column selection signal H may also have 32 bits.

In the column selection unit 600, a total of 8 column selection sections 601 are provided respectively for the plurality of memory banks BK0 through BK7.

FIG. 8 is a circuit diagram illustrating the configuration of a column selection section of the column selection unit shown in FIG. 7. Referring to FIG. 8, the column selection section 601 includes a lookup table part 610 and a select signal generation part 620.

The lookup table part 610 is configured to latch the slice address (J) SS_ADD<0:3> according to the row active signal (D′) ROW_ACT and the decoded bank address (F) BA_DEC, and to generate a latched slice address SS_LT_ADD<0:3>.

The lookup table part 610 is configured to maintain the latched slice address SS_LT_ADD<0:3> until a new slice address (J) SS_ADD<0:3> is inputted.

The lookup table part 610 includes first through fourth latches 611 through 614. The first through fourth latches 611 through 614 may be configured in the same way.

The first latch 611 is configured to latch the slice address (J) SS_ADD<0> according to the row active signal (D′) ROW_ACT and the decoded bank address (F) BA_DEC, and to generate the latched slice address SS_LT_ADD<0>.

The second latch 612 is configured to latch the slice address (J) SS_ADD<1> according to the row active signal (D′) ROW_ACT and the decoded bank address (F) BA_DEC, and generate the latched slice address SS_LT_ADD<1>.

The third latch 613 is configured to latch the slice address (J) SS_ADD<2> according to the row active signal (D′) ROW_ACT and the decoded bank address (F) BA_DEC, and generate the latched slice address SS_LT_ADD<2>.

The fourth latch 614 is configured to latch the slice address (J) SS_ADD<3> according to the row active signal (D′) ROW_ACT and the decoded bank address (F) BA_DEC, and generate the latched slice address SS_LT_ADD<3>.

The select signal generation part 620 includes a plurality of NAND gates ND1 through ND4 and a plurality of inverters IV1 through IV4.

The select signal generation part 620 is configured to output the latched slice address SS_LT_ADD<0:3> as the column selection signal (H) SS_LU<0:3> according to the column active signal (E′) COL_ACT.

FIG. 9 is a circuit diagram illustrating the configuration of the first latch shown in FIG. 8. Referring to FIG. 9, the first latch 611 includes a plurality of NAND gates ND11 through ND15 and a plurality of inverters IV11 and IV12. The first latch 611 latches the slice address (J) SS_ADD<0> according to the row active signal (D′) ROW_ACT and the decoded bank address (F) BA_DEC, and outputs the latched slice address SS_LT_ADD<0>.

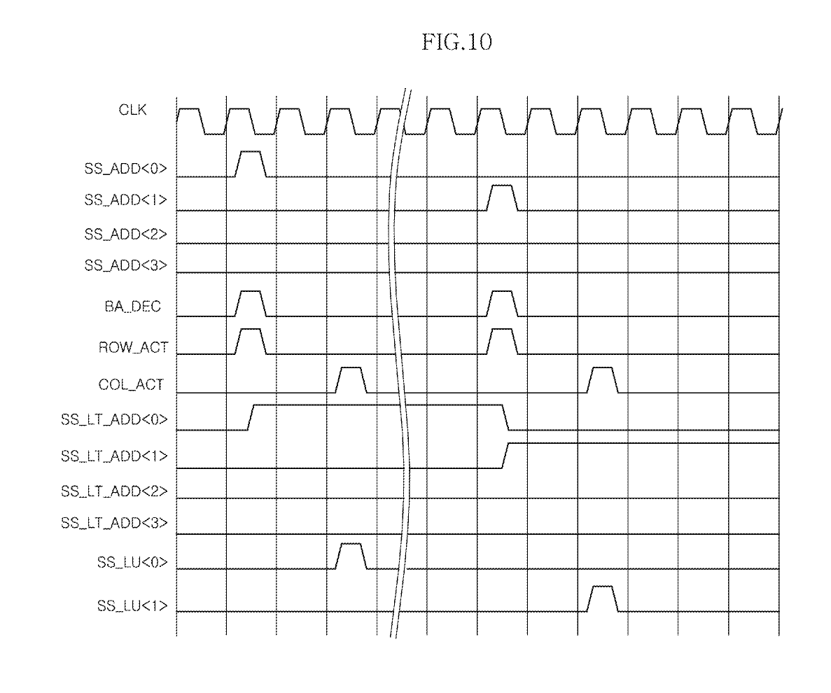

FIG. 10 is an operation timing diagram of the select signal generation circuit shown in FIG. 7. Referring to FIG. 10, the column selection section 601 latches the slice address SS_ADD<0> and generates the latched slice address SS_LT_ADD<0>, when the decoded bank address BA_DEC defines the memory bank BK0 and the row active signal ROW_ACT is activated.

When the column active signal COL_ACT is activated, the column selection signal SS_LU<0> for selecting a column of the memory bank BK0 corresponding to the slice address SS_LT_ADD<0> is generated.

Thereafter, when the decoded bank address BA_DEC re-defines memory bank BK0 and the row active signal ROW_ACT is activated, the column selection section 601 latches the slice address SS_ADD<1> and generates the latched slice address SS_LT_ADD<1>.

Then, when the column active signal COL_ACT is activated, the column selection signal SS_LU<1> for selecting the column of the memory bank BK0 corresponding to the slice address SS_LT_ADD<1> is generated.

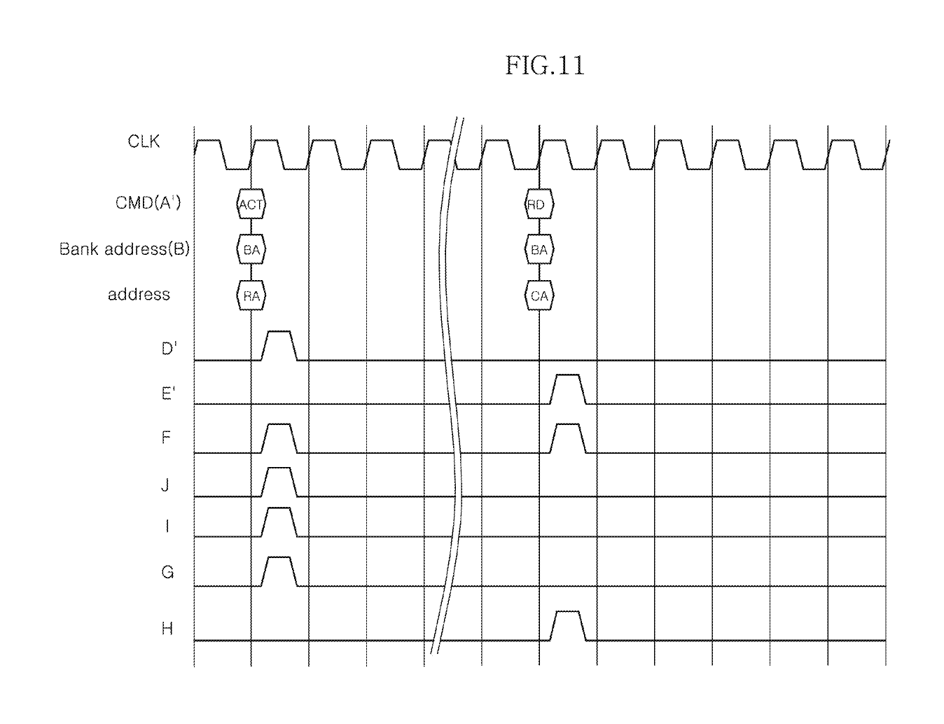

FIG. 11 is an operation timing diagram of the three-dimensional stacked semiconductor integrated circuit 100 in accordance with another embodiment of the present invention.

First, describing the row active cycle, as an active command ACT is inputted along with a bank address BA and a row address RA, the state machine 200 generates the row active signal D′.

The first address buffer 300 generates the decoded bank address F according to the bank address BA.

The second address buffer 400 generates the slice address J using a portion of the upper bits of the input signal I, that is, the row address RA.

The row selection unit 500 generates the row selection signal G according to the row active signal D′, the decoded bank address F and the slice address J.

A row active operation is performed, as one of the plurality of memory banks BK0 through BK7 is selected according to the row selection signal G.

At this time, the column selection unit 600 latches and stores the slice address J generated in the row active cycle, as described above.

Then, describing the column active cycle, as a read command RD is inputted along with a bank address BA and a column address CA, the state machine 200 generates the column active signal E′.

The first address buffer 300 generates the decoded bank address F according to the bank address BA.

The column selection unit 600 outputs, as the column selection signal H, the slice address SS_LT_ADD<0:3> latched in response to the column active signal E′.

A read operation is performed through the column active operation, in which one of the plurality of memory banks BK0 through BK7 is selected according to the column selection signal H.

As can be seen from the above-described embodiments of the present invention, since at least two of the memory banks aligned on the same line in the vertical direction are not simultaneously selected, the operation characteristics of a semiconductor integrated circuit can be improved.

While certain embodiments have been described above, those skilled in the art will understand that such embodiments are only examples. Accordingly, the three-dimensional stacked semiconductor integrated circuit and the control method thereof described herein should not be limited based on the described embodiments. Rather, the three-dimensional stacked semiconductor integrated circuit and the control method thereof described herein should only be limited in light of the claims that follow when taken in conjunction with the above description and accompanying drawings.

What is claimed is:

1. A three-dimensional stacked semiconductor integrated circuit including a plurality of stacked chips,
wherein the semiconductor integrated circuit is configured to simultaneously select the plurality of chips in response to an external command and an address, and to activate one of memory banks which are aligned on the same line in a vertical direction, among a plurality of memory banks included in the plurality of chips.

2. The three-dimensional stacked semiconductor integrated circuit according to claim 1, wherein the external command includes a chip selection signal composed of 1 bit.

3. The three-dimensional stacked semiconductor integrated circuit according to claim 1, wherein the address includes a bank address and a portion of upper bits of a row address.

4. The three-dimensional stacked semiconductor integrated circuit according to claim 1, wherein the plurality of chips are interfaced through TSVs (through-silicon vias).

5. The three-dimensional stacked semiconductor integrated circuit according to claim 1, wherein the semiconductor integrated circuit is configured to select memory banks which are aligned on the same line in the vertical direction, according to a bank address, and to activate one among the selected memory banks according to a row address.

6. A three-dimensional stacked semiconductor integrated circuit including a plurality of stacked chips, comprising:
in one of the plurality of chips, a select signal generation circuit configured to generate a selection signal for selectively activating a plurality of memory banks provided in the plurality of chips,
wherein the select signal generation circuit is configured to simultaneously select the plurality of chips in response to an external command and an address, and to activate one of memory banks which are aligned on the same line in a vertical direction, among the plurality of memory banks.

7. The three-dimensional stacked semiconductor integrated circuit according to claim 6, wherein the external command includes a chip selection signal composed of 1 bit.

8. The three-dimensional stacked semiconductor integrated circuit according to claim 6, wherein the address includes a bank address and a portion of upper bits of a row address.

9. The three-dimensional stacked semiconductor integrated circuit according to claim 6, wherein the plurality of chips are interfaced through TSVs.

10. The three-dimensional stacked semiconductor integrated circuit according to claim 6, wherein the select signal generation circuit is configured to simultaneously select the plurality of chips in response to a bank address and to activate one of the memory banks which are aligned on the same line in the vertical direction, among the plurality of memory banks, in response to a slice address for selecting memory banks which are aligned on the same line in a horizontal direction.

11. The three-dimensional stacked semiconductor integrated circuit according to claim 10, wherein the slice address is generated by decoding a portion of upper bits of a row address.

12. The three-dimensional stacked semiconductor integrated circuit according to claim 6, wherein the select signal generation circuit comprises:
a state machine configured to decode the external command and generate a row active signal and a column active signal;
a row selection unit configured to generate a row selection signal for activating any one row of the plurality of memory banks according to the row active signal, a decoded bank address and a slice address for selecting memory banks which are aligned on the same line in the horizontal direction; and
a column selection unit configured to generate a column selection signal for activating any one column of the plurality of memory banks according to the row active signal, the column active signal, the decoded bank address and the slice address.

13. The three-dimensional stacked semiconductor integrated circuit according to claim 12, wherein the column selection unit is configured to store the slice address in response to the row active signal and the decoded bank address, and to generate the slice address as the column selection signal in response to the column active signal.

14. A method for controlling a three-dimensional stacked semiconductor integrated circuit including a plurality of stacked chips, the method comprising the steps of:
selecting one from the group of memory banks aligned on the same line in a vertical direction among a plurality of memory banks included in the plurality of chips, by using a bank address; and
activating one of the memory banks of the selected group, by using a slice address.

15. The method according to claim 14, wherein the selecting step comprises the step of:
selecting simultaneously the plurality of chips, using a chip selection signal.

16. The method according to claim 14, wherein the slice address is an address for selecting memory banks which are aligned on the same line in a horizontal direction, among the plurality of memory banks included in the plurality of chips.

17. The method according to claim 14, wherein the slice address includes a portion of upper bits of a row address.

18. The method according to claim 14,
wherein the activating step is implemented for each of a row active cycle and a column active cycle, whereby the slice address generated in the row active cycle is stored and one of the memory banks of the selected group is activated using the stored slice address in the column active cycle.
